(19) United States
(12) Patent Application Publication
(10) Pub. No.: US 2022/0128909 A1
(43) Pub. Date: Apr. 28, 2022

(54) DETECTING METHOD FOR MANUFACTURING PROCESS OF SEMICONDUCTOR

(71) Applicant: CHANGXIN MEMORY TECHNOLOGIES, INC., Hefei City (CN)

(72) Inventor: Heng WANG, Hefei City (CN)

(21) Appl. No.: 17/647,659

(22) Filed: Jan. 11, 2022

Related U.S. Application Data
(63) Continuation of application No. PCT/CN2021/099757, filed on Jun. 11, 2021.

(30) Foreign Application Priority Data
Sep. 29, 2020 (CN) 202011047267.8

(51) Int. Cl. G03F 7/20

(52) U.S. Cl. CPC G03F 7/7085; G03F 7/70641; G03F 7/70091; G03F 7/70633; G03F 7/70625

(57) ABSTRACT

The present application provides a detecting method for manufacturing process of a semiconductor. Using a same photomask to expose different regions of a same wafer under different lighting conditions to acquire a plurality of photoetching patterns; and detecting the photoetching pattern. Detection results under the different lighting conditions can be acquired on the same wafer at the same time, thereby shortening detection time, improving production efficiency, and saving costs.

### CROSS-REFERENCES TO RELATED APPLICATIONS

This application is a continuation application of International Patent Application No. PCT/CN2021/099757, filed on Jun. 11, 2021, which claims priority to Chinese Patent Application No. 202011047267.8, filed with the Chinese Patent Office on Sep. 29, 2020 and entitled “A DETECTING METHOD FOR MANUFACTURING PROCESS OF SEMICONDUCTOR.” International Patent Application No. PCT/CN2021/099757 and Chinese Patent Application No. 202011047267.8 are incorporated herein by reference in their entireties.

### TECHNICAL FIELD

The present application relates to the field of semiconductor technologies, and in particular, to a detecting method for manufacturing process of a semiconductor.

### BACKGROUND

With development of manufacturing industries of semiconductors and integrated circuits, a photoetching technology has gradually become the key point of manufacturing integrated circuits.

An exposure system for the photoetching technology includes a photoetching lighting device, a photomask, a projection objective lens, and a workpiece platform for loading a wafer. A photomask pattern on the photomask is projected onto the wafer via the projection objective lens with the photoetching lighting device to form a photoetching pattern. Quality of the photoetching pattern formed on the wafer is different under different lighting conditions. In order to ensure the quality of the photoetching pattern, it is necessary to detect changes in lighting conditions.

### SUMMARY

The present application provides a detecting method for manufacturing process of a semiconductor, which can acquire detection results under different lighting conditions on a same wafer at the same time, thereby shortening detection time, improving production efficiency, and saving costs.

The present application provides a detecting method for manufacturing process of a semiconductor, including: using a same photomask to expose different regions of the same wafer under different lighting conditions to acquire a plurality of photoetching patterns; and detecting the photoetching pattern.

### BRIEF DESCRIPTION OF THE DIAGRAMS

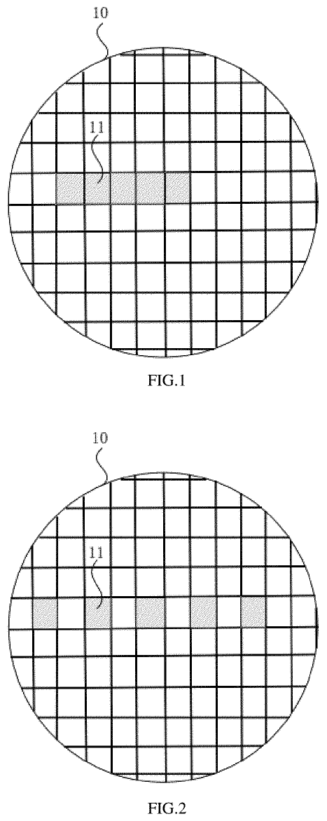

FIG. 1 is a schematic diagram of a pattern formed on a wafer by using a method of a first embodiment of the present application;

FIG. 2 is a schematic diagram of a pattern formed on a wafer by using a method of a second embodiment of the present application;

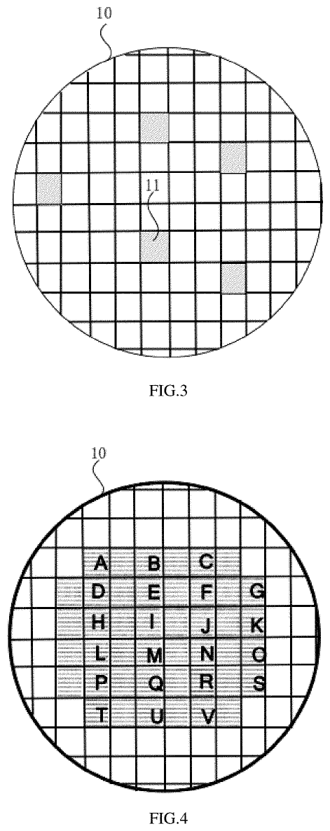

FIG. 3 is a schematic diagram of a pattern formed on a wafer by using a method of a third embodiment of the present application;

FIG. 4 is a schematic diagram of a pattern formed on a wafer by using a method of a fourth embodiment of the present application;

FIG. 5 is a corresponding table of an exposed region and irradiation conditions in the fourth embodiment of the present application; and

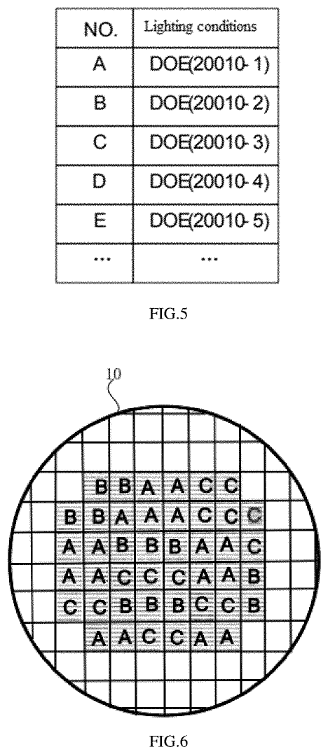

FIG. 6 is a schematic diagram of a pattern formed on a wafer by using a method of a fifth embodiment of the present application.

### DESCRIPTION OF THE INVENTION

The specific implementation of a detecting method for manufacturing process of a semiconductor according to the present application is described in detail below in conjunction with the accompanying drawings.

A detecting method for a manufacturing process of a semiconductor according to the present application includes: using a same photomask to expose different regions of a same wafer under different lighting conditions to acquire a plurality of photoetching patterns; and detecting the photoetching patterns.

The photomask can be a detecting photomask matched with an exposure system, or can be the photomask additionally arranged by a user as needed, such as a test photomask or a photomask for a mass-produced product.

A photomask pattern is provided on the photomask. The photomask patterns are distributed on different regions of the photomask. The photomask patterns can have various shapes. For example, the photomask patterns include a line, a circular hole, a fold line, or the like. The photomask pattern may be a discrete single pattern or a plurality of connected patterns.

The lighting conditions include a spot shape, a numerical aperture (NA) and a degree of coherence (Sigma). Specifically, the spot shape includes any one of a dipole shape, a quadrupole shape, a annular shape, and a circular shape. In other examples, the spot shape may be a freeform shape. For example, for an ASML flexray lighting system, various shapes of spots can be formed by adjusting reflection angles of a plurality of micro-mirrors.

The step of using a same photomask to expose different regions of a same wafer under different lighting conditions to acquire a plurality of photoetching patterns includes: exposing the photomask patterns on a same region on the photomask with the different lighting conditions. For example, the photomask is divided into four quadrants with a center point of the photomask as an origin of coordinates. Each of the quadrants corresponds to one region. In other embodiments, the region can also be divided according to needs of an engineer, such as a certain type of a distribution region of the photomask pattern, specifically, a mark pattern region, a test pattern region of a line array, or the like. Alternatively, the step of using a same photomask to expose different regions of a same wafer under different lighting conditions to acquire a plurality of photoetching patterns includes: exposing the same photomask pattern on the photomask under the different lighting conditions. For example, the photomask pattern may be an alignment mark, a weak-point window pattern, or the like. Different photomask patterns have different sensitivity to the lighting conditions. If different photomask patterns are used for exposure and detection, detection results may be incomparable. Therefore, this interference can be eliminated with the same photomask pattern, which makes the detection results more precise. In addition, an interference caused by a photomask manufacturing process, such as a surface roughness of the photomask itself and a uniformity of a size of the photomask pattern on the photomask, can also be eliminated with the same photomask pattern.

The different lighting conditions can be set such that the spot shape is the same, and at least one of the numerical aperture and the degree of coherence is different. The degree of coherence includes a degree of outer coherence (Gout) and a degree of inner coherence (Gin). The degree of outer coherence and the degree of inner coherence of the different lighting conditions have a difference range from 0 to 0.1, or one of the degree of outer coherence and the degree of inner coherence under the different lighting conditions have a difference range from 0 to 0.1. The numerical aperture of the different lighting conditions has a difference range from 0 to 0.05. The difference ranges of the degree of outer coherence and/or the degree of inner coherence of the different lighting conditions can be understood as ranges in which a maximum difference value and a minimum difference value of the degree of outer coherence and/or the degree of inner coherence of the different lighting conditions are located, for example, the degree of inner coherence of the different lighting conditions is 0.7, 0.72, 0.74, 0.76, 0.78, and 0.8 respectively; and the degree of outer coherence of the different lighting conditions are 0.8, 0.82, 0.84, 0.86, 0.88, and 0.9 respectively. The difference range of the numerical aperture of the different lighting conditions can be understood as ranges in which a maximum difference value and a minimum difference value of the numerical aperture of the different lighting conditions are located, for example, the numerical aperture of the different lighting conditions is 1.3, 1.31, 1.32, 1.33, 1.34, and 1.35, respectively. Such an arrangement ensures that an interference of the lighting conditions to an OPT is minimum. In addition, optimal lighting conditions can be selected according to optimal process results.

In other embodiments, the different lighting conditions further includes a difference in the spot shape. For example, in a case of the same photomask serving as a mask, the photomask is irradiated with the spots of different shapes, and the photomask pattern on the photomask is projected to different regions on the wafer. A photoresist on the wafer is developed to be able to obtain the photoetching patterns corresponding to the different spot shapes on the wafer. For example, the different regions on the same wafer are exposed with the same photomask by using the spots of the dipole shape, the quadrupole shape, the annular shape and the circular shape, respectively, and developed to obtain the photoetching patterns corresponding to the four spot shapes on the wafer.

In some specific implementations, the step of detecting the photoetching pattern includes: detecting a depth of focus (DOF) and/or an alignment precision (Overlay, OVL) of the photoetching pattern. Specifically, the same wafer is exposed with a focal length matrix (FM) by using the same photomask pattern under the different lighting conditions. For example, exposure with focal lengths of 0, ±20 nm, ±30 nm, and ±40 nm is performed at different locations of a first region of the wafer (for example, a left semicircle of the wafer) by using a first lighting condition. Exposure with the focal lengths of 0, ±20 nm, ±30 nm, and ±40 nm is performed at different locations of a second region of the wafer (such as a right semicircle of the wafer) by using a second lighting condition. By detecting a size and an image of the photoetching pattern obtained by the exposure under the different lighting conditions at different focal lengths, the depth of focus of the photoetching pattern under the different lighting conditions is determined. When an alignment mark pattern on the photomask is exposed by using the different lighting conditions, an alignment mark photoetching pattern can be obtained on the wafer. The alignment precision can be obtained under different lighting conditions by measuring the alignment mark photoetching pattern.

The detecting method for manufacturing process of the semiconductor of the present application further includes the following steps: presetting lighting parameters of formation of the lighting conditions, and automatically executing exposure steps according to the preset lighting parameters. Specifically, the lighting parameters can be preset in the exposure system to form a plurality of lighting conditions. In the exposure steps, with the same photomask pattern as the mask, different regions of the wafer are exposed with the preset lighting parameters by using the different lighting conditions to form a plurality of photoetching patterns.

In this embodiment, the wafer is a bare wafer, that is, the wafer is a wafer without any pattern provided. In other embodiments of the present application, the wafer may also be a wafer preset with the pattern.

FIG. 1 is a schematic diagram of a photoetching pattern formed on a wafer by using a method of the first embodiment of the present application. In FIG. 1, a shape of each of the photoetching patterns is not shown specifically, but only a position of each of the photoetching patterns is depicted. Referring to FIG. 1, in the first embodiment, the same photoetching mask pattern is configured as the mask. The plurality of photoetching patterns are formed in the different regions of the wafer 10. Exposed regions 11 (that is, regions formed with the photoetching pattern) are arranged adjacently. Specifically, in FIG. 1, the exposed region 11 is drawn with shading. It can be seen from FIG. 1 that a plurality of exposed regions 11 are arranged adjacently. In this embodiment, a number of exposed regions 11 is the same as a number of lighting conditions, that is, the lighting conditions are as many as the exposed regions. Only five of the exposed regions 11 are schematically shown in FIG. 1. In other embodiments of the present application, other numbers of the exposed regions 11 can be provided, which is not limited herein. The exposed region 11 may be one or more exposure units corresponding to the exposure system.

The detecting method for manufacturing process of the semiconductor of the present application can simultaneously obtain the detection results under the different lighting conditions on the same wafer, thereby shortening detection time, improving production efficiency, and saving costs.

In the first embodiment, a plurality of exposed regions are arranged adjacently, while in other embodiments of the present application, the exposed regions are arranged at intervals. Specifically, please refer to FIG. 2, FIG. 2 is a schematic diagram of a photoetching pattern formed on a wafer by using a method of the second embodiment of the present application, where in FIG. 2, a shape of each of the photoetching patterns is not shown specifically, but only a position of each of the photoetching patterns is depicted. The second embodiment is distinct from the first embodiment in that the exposed regions 11 are arranged at intervals. Specifically, in the second embodiment, the exposed regions 11 are arranged at intervals, and the adjacent exposed regions 11 are spaced with one exposure unit to avoid mutual interference between the adjacent exposed regions 11. In other embodiments of the present application, the exposed regions 11 are arranged at intervals, and the adjacent exposed regions 11 are spaced with a plurality of exposure units, which is not limited in the present application.

In the first embodiment, the plurality of exposed regions are arranged adjacently, and in the second embodiment, the plurality of exposed regions are arranged at intervals. It can be seen that in the first embodiment and the second embodiment, the exposed regions are arranged orderly, while in other embodiments of the present application, the exposed regions can also be arranged disorderly, that is, the exposed regions are randomly arranged. Specifically, please refer to FIG. 3, FIG. 3 is a schematic diagram of a photoetching pattern formed on a wafer by using a method of a third embodiment of the present application, where in FIG. 3, a shape of each of the photoetching patterns is not shown specifically, but only a position of each of the photoetching patterns is depicted. The third embodiment is distinct from the first embodiment in that the exposed regions 11 are arranged disorderly. Specifically, the plurality of exposed regions 11 are arranged at random positions of the wafer 10, but not arranged orderly according to a certain rule, which has the advantages that a step of selecting the exposed region is omitted, a procedure is simplified, and test time is further shortened.

In the first embodiment, lighting parameters are changed, and then lighting conditions are further changed, so that a spot shape formed on a wafer is different. In other embodiments of the present application, the lighting parameters can also be changed, and only the lighting conditions are fine-tuned. A basic spot shape remains unchanged. Specifically, please refer to FIG. 4, FIG. 4 is a schematic diagram of a pattern formed on a wafer by using a method of a fourth embodiment of the present application, where in FIG. 4, a shape of each photoetching pattern is not shown specifically, but only a position of each of the photoetching patterns is depicted. The fourth embodiment is distinct from the first embodiment in that basic shapes of a plurality of spots are unchanged, but only fine-tuned. For example, numerical values of degrees of outer coherence (Gout) of several lighting conditions constitute an arithmetic sequence. The photoetching pattern is detected to determine lighting conditions with optimal process results. The exposing subsequent wafer by using the lighting conditions with optimal process results. The optimal process results refer to the optimal parameters such as DOF, OVL, and CDU that can characterize quality of the photoetching process. Specifically, please refer to FIGS. 4 and 5, an exposed region corresponding to preset lighting conditions of DOE (20010-1) is A. Lighting parameters of the preset lighting conditions are fine-tuned to acquire a plurality of lighting conditions, for example, Gout of the lighting conditions of DOE (20010-1), DOE (20010-2), DOE (20010-3), DOE (20010-4), DOE (20010-5) . . . is 0.8, 0.81, 0.82, 0.83, 0.84 . . . , or the like, to which the exposed regions corresponding respectively are A, B, C, D, E, or the like. In this embodiment, by fine-tuning the degree of outer coherence of the lighting conditions, the optimal lighting conditions can be filtered out, thereby improving an alignment process window of a product. For example, as shown in FIG. 4, the photoetching pattern of the exposed region is detected, and it is found that the photoetching patterns of an exposed region R and an exposed region T have best alignment process windows. Then, the lighting conditions corresponding to the exposed region R and the exposed region T serve as the lighting conditions for subsequent formation of the photoetching patterns, thereby improving a process window of the product and increasing a yield.

A photoetching process is a common process often used in a manufacturing process of a semiconductor. With development of semiconductor manufacturing technologies and development of design and manufacturing of an integrated circuit, photoetching imaging technologies develop accordingly, and a feature size of a semiconductor device is also continuously reduced. It is necessary to pay attention to interlayer alignment during photoetching, that is, alignment registration, to ensure registration between a current pattern and an existing pattern on a silicon slice. Therefore, in order to achieve a good performance and a high yield of a product, it is hoped to achieve higher alignment precision. Specifically, the alignment precision refers to a registration precision (an overlaying precision) between a pattern on a surface of the silicon slice and a pattern on a current mask. The overlaying precision is one of important performance indicators of a modern high-precision step-and-scan projection photoetching machine, and is also an important part of novel photoetching technologies to be considered. The alignment precision seriously affects a yield and a performance of a product. Improving the alignment precision of the photoetching machine is also the key point of determining a minimum unit size.

In the first embodiment, the wafer is a bare wafer. However, in this embodiment, the wafer is a wafer with a preset pattern, that is, a wafer configured to measure the alignment precision. For example, the wafer is a wafer (a HOLY wafer) using an exposure system to monitor OVL. Specifically, please refer to FIG. 6, FIG. 6 is a schematic diagram of a pattern formed on a wafer using a method of a fifth embodiment of the present application, where in FIG. 6, a shape of each photoetching pattern is not shown specifically, but only a position of each of the photoetching patterns is depicted. The fifth embodiment is distinct from the first embodiment in that the wafer 10 is a wafer with a preset pattern. During exposure, the pattern can be formed in both a region of the wafer with the preset pattern and a region of the wafer without the preset pattern. Specifically, referring to FIG. 6, a region marked by an exposed region A is an region with the preset pattern on the wafer, that is, a region configured to monitor an alignment region (OVL), and regions marked by exposed regions B and C are regions without any patterns. The same photomask pattern can be configured as a mask. Under different lighting conditions, different regions (such as the exposed regions A, B, and C) of the wafer are exposed to acquire a plurality of photoetching patterns to monitor a relation between alignment precision and the lighting conditions.

The above merely describes preferred embodiments of the present application. It should be pointed that for those skilled in the art, some improvements and polishments, which shall also fall within the protection scope of the present application, may be made without departing the principle of the present application.

What is claimed is:

1. A detecting method for manufacturing process of a semiconductor, comprising:
using a same photomask to expose different regions of a same wafer under different lighting conditions to acquire a plurality of photoetching patterns; and
detecting the photoetching pattern.

2. The detecting method for manufacturing process of the semiconductor according to claim 1, wherein the lighting conditions comprise a spot shape, a numerical aperture, and a degree of coherence.

3. The detecting method for manufacturing process of the semiconductor according to claim 2, wherein the step of using a same photomask to expose different regions of a same wafer under different lighting conditions to acquire a plurality of photoetching patterns comprises: exposing a photomask pattern of a same region on the photomask under different lighting conditions.

4. The detecting method for manufacturing process of the semiconductor according to claim 2, wherein the step of using a same photomask to expose different regions of a same wafer under different lighting conditions to acquire a plurality of photoetching patterns comprises: exposing a same photomask pattern on the photomask under the different lighting conditions.

5. The detecting method for manufacturing process of the semiconductor according to claim 3, wherein
the different lighting conditions are set as follows: the sport shape is the same, and at least one of the numerical aperture and the degree of coherence is different.

6. The detecting method for manufacturing process of the semiconductor according to claim 5, wherein the degree of coherence comprises a degree of outer coherence and a degree of inner coherence, and the degree of outer coherence and the degree of inner coherence under the different lighting conditions have a difference range from 0 to 0.1, or one of the degree of outer coherence and the degree of inner coherence under the different lighting conditions have a difference range from 0 to 0.1.

7. The detecting method for manufacturing process of the semiconductor according to claim 5, wherein the numerical aperture of the different lighting conditions has a difference range from 0 to 0.05.

8. The detecting method for manufacturing process of the semiconductor according to claim 6, wherein
numerical values of degrees of the outer coherence of several of the lighting conditions constitute an arithmetic sequence;
the lighting conditions with optimal process results are determined by detecting the photoetching pattern; and
exposing subsequent wafer by using the lighting conditions with the optimal process results.

9. The detecting method for manufacturing process of the semiconductor according to claim 1, wherein the step of detecting the photoetching pattern comprises:
detecting at least one of a focus depth or alignment precision of the photoetching pattern.

10. The detecting method for manufacturing process of the semiconductor according to claim 1, wherein
different lighting conditions comprises a difference in the sport shape.

11. The detecting method for manufacturing process of the semiconductor according to claim 2, wherein
the spot shape comprises any one of a dipole shape, a quadrupole shape, an annular shape and a circular shape.

12. The detecting method for manufacturing process of the semiconductor according to claim 2, wherein
the spot shape comprises a shape of a spot formed by adjusting reflection angles of a plurality of micro-mirrors.

13. The detecting method for manufacturing process of the semiconductor according to claim 1, wherein the exposed regions are arranged adjacently or spaced apart on the wafer.

14. The detecting method for manufacturing process of the semiconductor according to claim 1, wherein the wafer is a wafer with a preset pattern, and the different regions of the wafer comprise at least one of a region with the preset pattern or a region without the preset pattern.
